(19) United States
(12) Patent Application Publication
(10) Pub. No.: US 2024/0078942 A1
(43) Pub. Date: Mar. 7, 2024

(54) DISPLAY MODULE AND DISPLAY PANEL

(71) Applicant: FOSHAN NATIONSTAR OPTOELECTRONICS CO., LTD., Foshan (CN)

(72) Inventors: Kuai QIN, Foshan (CN); Heng GUO, Foshan (CN); Shaojia XIE, Foshan (GD); Bin CAI, Foshan (CN); Caineng HUO, Foshan (CN); Kailiang FAN, Foshan (CN)

(73) Assignee: FOSHAN NATIONSTAR OPTOELECTRONICS CO., LTD., Foshan (CN)

(21) Appl. No.: 18/140,001

(22) Filed: Apr. 27, 2023

(30) Foreign Application Priority Data
Apr. 28, 2022 (CN) 202210471320.X

(51) Int. Cl. G09G 3/00; H01L 25/075; H01L 27/15; H01L 33/62

(52) U.S. Cl. CPC G09G 3/006; H01L 25/0753; H01L 27/156; H01L 33/62; G09G 2330/12

(57) ABSTRACT

A display module includes a substrate, m rows and n columns of pad sets, m*n sets of light emitting chip sets and multiple pins. The substrate includes a first surface and a second surface disposed opposite to each other. Each set of pad sets among the m rows and n columns of pad sets includes three pairs of pads, and first pads in the each set of pad sets are electrically connected. In a same set of light emitting chips, each of first electrodes of the light emitting chips is connected to a respective one of first pads of one set of pad sets among the m rows and n columns of pad sets, and each of second electrodes of the light emitting chips is connected to a respective one of second pads of a same set of pad sets.

### CROSS-REFERENCE TO RELATED APPLICATION(S)

This application claims priority to Chinese Patent Application No. 202210471320.X filed Apr. 28, 2022, the entirety of which is incorporated herein by reference in its entirety.

### TECHNICAL FIELD

Embodiments of the present disclosure relate to the field of display technologies, and in particular to, a display module and a display panel.

### BACKGROUND

Alight emitting diode (LED) display module are widely favored by users as new display technologies for the advantages of their energy-saving, environmental-friendly, efficient, and the like, however, as LED display screens continue to evolve, there is more and more demanding demands on visual feeling, contrast, brightness, life, and the like of the LED display screens, and thus the test requirements for the LED display module are also higher and higher.

In the related art, prior to testing the LED display module, a direction selection for the LED display module is required, that is, a placement direction of the LED display module within a test apparatus has a uniform direction, so as to ensure that a test pin of the test apparatus is correspondingly connected to a pin of the LED display module during a test. Exemplarily, the direction selection may be achieved by laser identifying white oil on the LED display module through a vibration disk, in this method, the cost is low, while the precision of a direction selection result is also relatively low, and an area of the white oil is required to be relatively large. A current LED display module with a spacing less than 0.5 μm has multiple display module pins, so that a large area of white oil cannot be placed on the LED display module, in this method, the use is limited. In addition, the direction selection may also be achieved by acquiring images through a vibration disk with a charge-coupled device (CCD), in this method, the cost is relatively high and the precision of a direction selection result is relatively high. In a direction selection process, when an initial placement direction of the LED display module does not coincide with the uniform direction, the placement direction of the LED display module needs to be adjusted so that the placement direction of the LED display module coincides with the uniform direction, it is ensured that a test pin of each LED display module is correspondingly connected to the test pin of the test apparatus, so that a test of the LED display module is achieved. In summary, the direction selection process is relatively complicated, so that the test complexity of the LED display module is increased and the test efficiency of the LED display module is reduced.

### SUMMARY

The present disclosure provides a display module and a display panel, to improve the test efficiency of the display module and reduce the test cost.

In a fist aspect, an embodiment of the present disclosure provides a display module. The display module includes a substrate, m rows and n columns of pad sets arranged in an array, m*n sets of light emitting chip sets and multiple pins. The substrate includes a first surface and a second surface disposed opposite to each other. The pad sets are disposed on the first surface and each include three pairs of pads, each pair of pads among the three pairs of pads includes a first pad and a second pad, and first pads in the each set of pad sets are electrically connected, where m≥2 and n≥2. The m*n sets of light emitting chip sets are disposed on a side of the pad sets facing away from the first surface, where each set of the m*n sets of light emitting chip sets includes three types of light emitting chips, and in the same set of light emitting chip sets, each of first electrodes of light emitting chips is connected to a respective one of first pads of one set of the pad sets, and each of second electrodes of light emitting chips is connected to a respective one of second pads of the same one set of pad sets. A plurality of pins include n first electrode pins and 3 m second electrode pins and are disposed on the second surface, where one first electrode pin among the n first electrode pins is electrically connected to a common first pad corresponding to first electrodes of light emitting chips in one row of light emitting chip sets among the m*n sets of light emitting chip sets, and one second electrode pin among the 3 m second electrode pins is electrically connected to a second pad corresponding to a second electrode of the same type of light emitting chips in one column of light emitting chip sets among the m*n sets of light emitting chip sets; and the n first electrode pins are symmetrically distributed about a geometric center of the second surface, and the 3 m second electrode pins are symmetrically distributed about the geometric center of the second surface.

Optionally, the plurality of pins are divided into four types of function pins which are first function pins, second function pins, third function pins and fourth function pins, respectively, the first function pins correspond to the n first electrode pins, the second function pins correspond to second electrode pins corresponding to of a first type of light emitting chips, the third function pins correspond to second electrode pins corresponding to a second type of light emitting chips, the fourth function pin corresponds to second electrode pins corresponding to a third type of light emitting chips, and the four types of function pins are symmetrically distributed about the geometric center of the second surface.

Optionally, the second surface of the substrate is square, the first function pins are rotationally symmetric with respect to 90°, the second function pins are rotationally symmetric with respect to 90°, the third function pins are rotationally symmetric with respect to 90°, and the fourth function pins are rotationally symmetric with respect to 90°.

Optionally, the substrate includes N metal line layers sequentially stacked, and includes an insulating plate between adjacent metal line layers, where the N metal line layers are electrically connected by conductive via holes on the insulating plate, and N≥2.

Optionally, each of the first pad and the second pad is electrically connected to a respective one of the plurality of pins located on the second surface of the substrate through the conductive via holes, respectively, or each of the first pad and the second pad is electrically connected to a respective one of the plurality of pins located on the second surface of the substrate through the conductive via holes and the N metal line layers of the substrate, respectively.

Optionally, conductive via holes of each column of common first pads are disposed between the same adjacent two rows of light emitting chip sets.

Optionally, the display module includes 16p sets of pad sets arranged in a square-shaped matrix, each set of pad sets among the 16p sets of pad sets includes the three pairs of pads, first pads of each column of pad sets are electrically connected to the n first electrode pins, respectively, and second pads of the same type of light emitting chips of each row of pad sets are electrically connected to the 3 m second electrode pins, respectively; and the plurality of pins are arranged in a square-shaped matrix, where p is an integer greater than or equal to 1.

Optionally, the substrate includes a first metal line layer, a second metal line layer, a third metal line layer and a fourth metal line layer which are stacked; the 16p sets of pad sets are arranged in a square-shaped matrix on the first metal line layer; and the plurality of pins are arranged in a square-shaped matrix on the fourth metal line layer; and
the first metal line layer is further provided with a first connection line and a second connection line, in a row direction of the pad sets, second pads which correspond to the same type of light emitting chip and are in an i-th column of pad sets and an (i+1)-th column of pad sets in the same row are connected by the first connection line, and first pads of the pad sets in the same column are connected through the second connecting line; where i is an odd number greater than or equal to 1 and less than 4p.

Optionally, second pads of an i-th column of the pad sets and second pads of an (i+1)-th column of the pad sets in the same row are disposed adjacent to each other in the row direction of the pad sets.

Optionally, the light emitting chips corresponding to the second pads in the same row of the pad sets have the same distribution of types in a column direction.

Optionally, the display module further includes a welding layer, where the welding layer is disposed on a side of the pad sets facing away from the first surface, electrodes of light emitting chip sets are connected to the pad sets via the welding layer, respectively.

Optionally, a perpendicular projection of each of the plurality of pins on the substrate is polygonal or circular.

In a second aspect, an embodiment of the present disclosure further provides a display panel. The display panel includes the display module provided in the first aspect.

According to technical schemes of the embodiments of the present disclosure, the pins on the substrate are symmetrically distributed about the function center, where the function center is the geometric center of the second surface, so that after the display module is rotated by a predetermined angle, a corresponding type of function of the pin at a position on the second surface before rotation is the same as a corresponding type of function after rotation thereof. When the display module is tested and the placement direction of the display module does not coincide with the uniform direction, the electrodes on the display module and the test electrode of the test apparatus may be connected to each other, so that the test may be performed without the direction selection, whereby the test process of the display module is simplified, the test efficiency of the display module is improved, and thus the test cost is reduced.

### BRIEF DESCRIPTION OF DRAWINGS

FIG. 1 is a schematic structural diagram of a display module provided in an embodiment of the present disclosure;

FIG. 2 is top structural schematic diagram of a second surface provided in an embodiment of the present disclosure;

FIG. 3 is top structural schematic diagram of a first surface provided in an embodiment of the present disclosure;

FIG. 4 is a schematic structural diagram of a second metal line layer provided in an embodiment of the present disclosure;

FIG. 5 is a schematic structural diagram of a third metal line layer provided in an embodiment of the present disclosure;

FIG. 6 is a connection principle diagram of a light emitting chip in a display module provided in an embodiment of the present disclosure; and

FIG. 7 is a front structural schematic diagram of another display module provided in an embodiment of the present disclosure.

### DETAILED DESCRIPTION

The present disclosure will be further described in detail in conjunction with the drawings and embodiments below. It should be understood that the specific embodiments described herein are merely used for explaining the present disclosure and are not intended to limit the present disclosure. In addition, it should also be noted that, for ease of description, only some, but not all, of the structures related to the present disclosure are shown in the drawings.

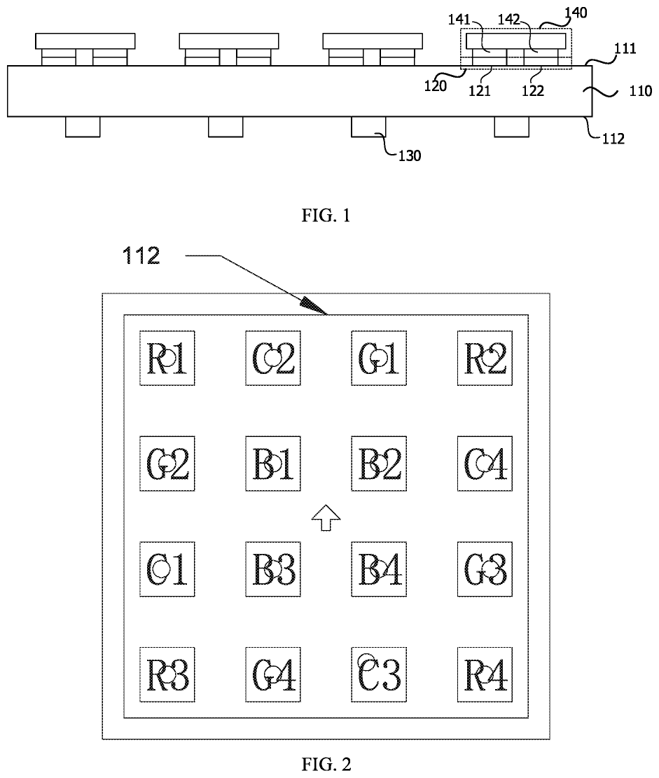

FIG. 1 is a schematic structural diagram of a display module provided in an embodiment of the present disclosure, and FIG. 2 is top structural schematic diagram of a second surface provided in an embodiment of the present disclosure. As shown in FIGS. 1 and 2, the display module includes a substrate 110, m rows and n columns of pad sets 120 arranged in an array, m*n sets of light emitting chip sets 140 and multiple pins 130.

The substrate 110 includes a first surface 111 and a second surface 112 disposed opposite to each other.

The m rows and n columns of pad sets 120 arranged in an array are disposed on the first surface 111, where each set of pad sets 120 includes three pairs of pads, each pair of pads includes a first pad 121 and a second pad 122, and first pads 121 in the each set of pad sets 120 are electrically connected, where m≥2 and n≥2.

The m*n sets of light emitting chip sets 140 are disposed on a side of the pad sets 120 facing away from the first surface 111, each set of light emitting chip sets 140 includes three types of light emitting chips, and in the same set of light emitting chip sets 140, each of first electrodes 141 of the light emitting chips is connected to a respective one of first pads 121 of one set of pad sets 120, and each of second electrodes 142 of the light emitting chips is connected to a respective one of second pads 122 of the same set of pad sets 120.

The multiple pins 130 include n first electrode pins and 3 m second electrode pins and are disposed on the second surface 112, where one first electrode pin among the n first electrode pins is electrically connected to a common first pad 121 corresponding to first electrodes of light emitting chips in one row of light emitting chip sets, and one second electrode pin among the 3 m second electrode pins is electrically connected to a second pad 122 corresponding to a second electrode of the same type of light emitting chip in one column of light emitting chip sets; the n first electrode pins are symmetrically distributed about a function center, and the 3 m second electrode pins are symmetrically distributed about the function center, where the function center is a geometric center of the second surface 121.

Specifically, the pads within the pad sets 120 may be copper pillars, for connecting electrodes of light emitting chips within the light emitting chip set 140. The light emitting chip may be a flip-chip, which may ensure reliability of the light emitting chip while having characteristics of high brightness and high contrast. Different types of light emitting chips are light emitting chips with different light emitting colors. The first pads 121 of each set of pad sets 120 are connected, so that first electrodes 121 of three types of light emitting chips within each set of light emitting chip sets 140 are connected, that is, first electrodes 121 of all light emitting chips within each set are electrically connected. When the first electrode 121 is a cathode, a common cathode connection of all light emitting chips in each set may be achieved. The each set of pad sets 120 includes three pairs of pads, and each set of light emitting chip sets 140 may correspondingly disposed to include three light emitting chips, each of the three light emitting chips may have a different light emitting color. Exemplarily, the each set of pad sets 120 includes three pairs of pads, and each set of light emitting chip sets 140 may correspondingly disposed to include three light emitting chips, one light emitting chip is a light emitting chip whose light emitting color is red, another light emitting chip is a light emitting chip whose light emitting color is green, and still another light emitting chip is a light emitting chip whose light emitting color is blue.

In the same set of pad sets 120, the pads may be divided into multiple function pads according to the pins of the light emitting chips to which the pads are connected are different, that is, the pads specifically include a first pad 121 and a second pad 122, where the first electrode 141 of the light emitting chip is connected to the first pad 121, and the second electrode 142 of each light emitting chip is connected to the second pad 122. Different pads are correspondingly connected to the pins 130, so that the pins 130 may be divided into multiple function pins according to the pads correspondingly connected to the pins 130, the multiple function pins specifically include a pin corresponding to the first pad 121 and a pin corresponding to the second pad 122 corresponding to the second electrode of each light emitting chip. Exemplarily, when each set of pad sets 120 includes three pairs of pads, and the light emitting chip set 140 correspondingly connected to the each set of pad sets 120 may include three types of light emitting chips, then the pads within the each set of pad sets 120 may be divided together into four types of function pads, i.e., a first pad correspondingly connected to the first electrode of the light emitting chip and serving as a first function pad, a second pad corresponding to a second electrode of a light emitting chip of a first type and serving as a second function pad, a second pad corresponding to a second electrode of a second light emitting chip of a second type and serving as a third functional pad, and a second pad corresponding to a second electrode of a third light emitting chip of a third type and serving as a fourth functional pad. Therefore, the pins 130 may be divided into four types of function pins in total, i.e., a first function pin corresponding to the first function pad, a second function pin corresponding to the second function pad, a third function pin corresponding to the third function pad, and a fourth function pin corresponding to the fourth function pad. The first function pin is the first electrode pin, and the second function pin, the third function pin and the fourth function pin are the second electrode pin.

Specifically, the second surface 112 is a regular polygon, and when the pins corresponding to the pads are symmetrically distributed about the function center, where the function center is the geometric center of the second surface 112, the multiple pins 130 may be distributed in an array. After the display module rotates a predetermined angle, the function of the pin 130 at a position on the second surface 112 before the rotation is the same as the function after the rotation in terms of a type. When the display module is tested and a placement direction of the display module does not coincide with the uniform direction, the electrodes on the display module and a test electrode of a test apparatus may be connected to each other, so that the test may be performed without the direction selection, whereby the test process of the display module is simplified, the test efficiency of the display module is improved, and thus the test cost is reduced. Preferably, the second surface 112 of the substrate 110 is square, the first function pin are rotationally symmetric with respect to 90°, the second function pin are rotationally symmetric with respect to 90°, the third function pin are rotationally symmetric with respect to 90°, and the fourth function pin are rotationally symmetric with respect to 90°. Exemplarily, referring to FIG. 2, the second surface 112 of the substrate 110 is square, when the display module includes sixteen sets of pad sets 120, each set of pads 120 includes three pairs of pads, the light emitting chip set 140 includes three types of light emitting chips, i.e., a red light emitting chip, a green light emitting chip and a blue light emitting chip, respectively, when each pair of pads is connected to a respective one of the three types of light emitting chips, the pins 130 are then divided together into four types of function pins, i.e., a first function pin corresponding to the first electrode, a second function pin corresponding to a second electrode of the red light emitting chip, a third function pin corresponding to a second electrode of the green light emitting chip, and a fourth function pin corresponding to a second electrode of the blue light emitting chip. The sixteen sets of pad sets 120 together correspond to four first function pins, four second function pins, four third function pins, and four fourth function pins, the four first function pins are a first pin C1, a second pin C2, a third pin C3 and a fourth pin C4, respectively, the four second function pins are a fifth pin R1, a sixth pin R2, a seventh pin R3, and an eighth pin R4, respectively, the four third function pins are a ninth pin G1, a tenth pin G2, an eleventh pin G3, and a twelfth pin G4, respectively, and the fourth function pins are a thirteenth pin B1, a fourteenth pin B2, a fifteenth pin B3, and a sixteenth pin B4, respectively. The arrangement of the pins 130 is shown in FIG. 2, so that after the second surface 112 is rotated with the geometric center of the square as the center of rotation, the corresponding function of the pin 130 at a position on the second surface 112 before the rotation is the same as the corresponding function after the rotation in terms of a type. For example, prior to the rotation, an upper left corner of the second surface 112 is provided with a fifth pin R1, i.e. a pin corresponding to the second electrode of the red light emitting chip, after being rotated by 90°, a upper left corner of the second surface 112 is provided with the sixth pin R2 and the seventh pin R3, i.e. a pin corresponding to the second electrode of the red light emitting chip, that is, the first function pin are rotationally symmetric with respect to 90°, the second function pin are rotationally symmetric with respect to 90°, the third function pin are rotationally symmetric with respect to 90°, and the fourth function pin are rotationally symmetric with respect to 90°. When the display module is tested and the placement direction of the display module does not coincide with the uniform direction, the electrodes on the display module and the test electrode of the test apparatus may be connected to each other, so that the test may be performed without the direction selection, whereby the test process of the display module is simplified, the test efficiency of the display module is improved, and thus the test cost is reduced.

It should be noted that types of light emitting chips of each set of light emitting chip sets 140 may be the same or different, as long as an arrangement manner of the pins 130 on the second surface 112 satisfies that the pins 130 are symmetrically distributed about the function center, where the function center is the geometric center of the second surface 112.

On the basis of the above technical schemes, a perpendicular projection of the pins 130 on the substrate 110 is polygonal or circular.

Specifically, the pins 130 may take the form of a ball grid array, and the pins 130 may take the form of a polygonal or circular structure, which may allow a welding area of the pins 130 to reach a maximum value with a fixed spacing between the pins 130.

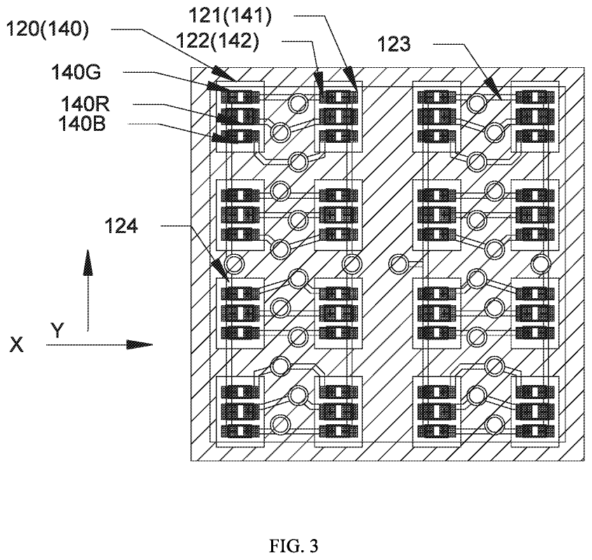

FIG. 3 is top structural schematic diagram of a first surface provided in an embodiment of the present disclosure, referring to FIGS. 1 to 3, the display module includes 16p sets of pad sets 120 arranged in a square-shaped matrix, each set of pad sets 120 includes the three pairs of pads, first pads 121 of each column of pad sets 120 are electrically connected to the first electrode pins, respectively, and second pads 122 of a same type of light emitting chip of each row of pad sets 120 are electrically connected to the second electrode pins, respectively; and the multiple pins 130 are arranged in the square-shaped matrix, where p is an integer greater than or equal to 1.

Specifically, when each set of pad sets 120 includes three pairs of pads, each set of light emitting chip sets 140 may include three types of light emitting chips, and at this time, the pins 130 correspond to four types of function pins, and one for each type of light emitting chip is exemplarily shown in FIG. 3, and one set of light emitting chip sets 140 corresponds to four pins 130. The display module is disposed to include 16p sets of pad sets 120, so that a number of pins 130 may be arranged in the square-shaped matrix, and pins with different functions are disposed to be distributed in a central symmetric manner with the geometric center of the second surface 112 as the center, whereby the pins 130 with different functions may be symmetrically distributed about the function center, where the function center is the geometric center of the second surface 112.

It should be noted that, in FIG. 3, it is exemplarily shown that when p is equal to 1, the display module includes 16 sets of pads 120. In other embodiments, when p is an integer greater than 1, the display module may include 32 sets of pad sets 120, 64 sets of pad sets 120, which also enables a number of the pins are arranged in the square-shaped matrix.

The substrate 110 includes N metal line layers sequentially stacked, and includes an insulating plate between adjacent metal line layers. The N metal line layers are electrically connected by conductive via holes on the insulating plate, where N≥2. Specifically, the first pad 121 and the second pad 122 are electrically connected to a respective one of pins located on the second surface of the substrate 10 through the conductive via holes, respectively. Alternatively, the first pad and the second pad are electrically connected to a respective one of pins located on the second surface of the substrate 110 through the conductive via holes and the metal line layers located on the substrate 110, respectively. Further, conductive via holes electrically connected to the second pads correspondingly disposed in each set of light emitting chip sets 140 are not in a same vertical line. In addition, the conductive via holes of each column of common first pads 121 are disposed between the same two adjacent rows of light emitting chip sets. Therefore, a problem that the size of the LED display module is difficult to be further reduced due to the limitation of the sizes of the pad and the metal line layer in the related art is solved, and the integration level of the light emitting chip of the LED display module is improved while the stability of the circuit is ensured.

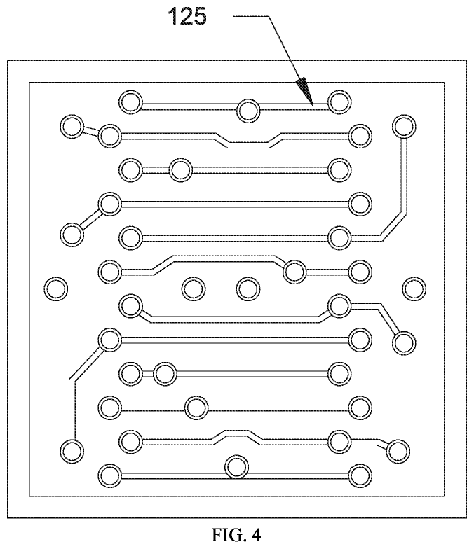

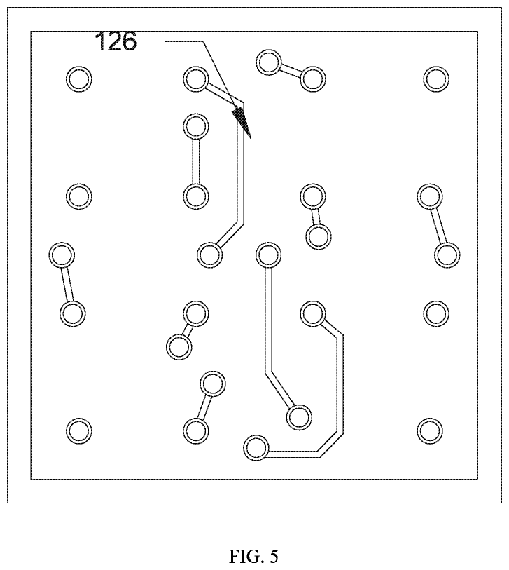

FIG. 4 is a schematic structural diagram of a second metal line layer provided in an embodiment of the present disclosure, and FIG. 5 is a schematic structural diagram of a third metal line layer provided in an embodiment of the present disclosure. As shown in FIGS. 2 to 5, N=4, the substrate includes a first metal line layer, a second metal line layer, a third metal line layer and a fourth metal line layer disposed in a stacked manner; the 16p sets of pad sets 120 are arranged in the square-shaped matrix on the first metal line layer; and the multiple pins 130 are arranged in the square-shaped matrix on the fourth metal line layer; and the first metal line layer is also provided with a first connection line 123 and a second connection line 124, in a row direction X in which the pad sets are arranged, second pads 122 corresponding to the same type of light emitting chip in an i-th column of pad sets 120 and an (i+1)-th column of pad sets 120 in the same row are connected by the first connection line 123, and first pads 121 of the pad sets 120 in the same column are connected through the second connection line 124; where i is an odd number greater than or equal to 1 and less than 4p; the second metal line layer is also provided with a third connection line 125, the first connection lines 123 in the same row are connected by the third connection line 125, the third metal line layer is provided with a fourth connection line 126, the second connection line 124 is connected to the pin 130 by the fourth connection line 126; and the first connection line 123 is connected to the pin 130 by the third connection line 125 and the fourth connection line 126.

When the first metal line layer, the second metal line layer, the third metal line layer and the fourth metal line layer are disposed in the stacked manner, the first metal line layer is the first surface 111 of the substrate 110, and the fourth metal line layer is the second surface 112 of the substrate 110. The pad sets 120 disposed on the first metal line layer may be arranged in the square-shaped matrix, each set of pad sets 120 are used as one element of the matrix, so as to form a matrix arrangement with the pad sets 120 as elements, so that the first pad 121 and the second pad 122 in the pad sets 120 are arranged in a matrix, and the first pad 121 and the second pad 122 may be electrically connected to the pins in sequence, thus the arrangement of the connection lines is simplified.

In addition, the first metal line layer is also provided with the first connection line 123 and the second connection line 124, the first connection line 123 is used for connecting second pads 122 of corresponding same light emitting chips within different column of pad sets 120 in the same row, and at the same time, the third connection line 125 connects the first connection line 123 in the same row, so that the pad sets 120 in the same row may be point-connected, second electrodes 122 of the same type of light emitting chip in the light emitting chip sets 140 corresponding to the pad sets 120 in the same row are connected, whereby signals are provided for second electrode 122 of the same type of light emitting chip within the light emitting chip sets 140 in the same row through one pin 130, the arrangement of the pins 130 is reduced, and further, the arrangement of the pins 130 being symmetrically distributed about a function center, where the function center is a geometric center of the second surface 112, while the third connection line 125 is disposed on the second metal line layer, which may simplify the design of lines on the first metal line layer and reduce the risk of being shorted when patching the light emitting chip on the first metal line layer. The second connection lines 124 are used for connecting all of the first pads 121 within the same column of pad sets 120, whereby common cathode or common anode connections to the light emitting chips within the corresponding light emitting chip set 140 of the same column of pad sets 120 are implemented.

Exemplarily, when p is equal to 1, the display module includes 16 sets of pad sets 120 in total arranged in a square-shaped matrix, and 16 sets of pad sets 120 arranged in a 4*4 matrix are included on the first metal line layer. At this time, second pads 122 of a corresponding one of the light emitting chips within pad sets 120 located in first row and first column may be connected to second pads 122 of a corresponding one of the light emitting chips within a second column of pad sets 120 through the first connection line 123, second pads 122 of a corresponding one of the light emitting chips within a third column of pad sets 120 may be connected to second pads 122 of a corresponding one of the light emitting chips within a fourth column of pad sets 120 through the first connection line 123, then the two first connection lines 123 are connected by the third connection lines 125, so that second pads 122 corresponding to the same type of light emitting chip in a first row of 4 sets of pad sets 120 may be connected, and further second electrodes 142 of the same light emitting chip within 4 sets of light emitting chip sets 140 corresponding to a first row of 4 sets of pad sets may be connected.

For example, each set of light emitting chip sets 140 includes a red light emitting chip 140R, a green light emitting chip 140G and a blue light emitting chip 140B, then second electrodes 142 of the red light emitting chip 140R in each set of light emitting chip sets 140 in the same row are connected, second electrodes 142 of the green light emitting chip 140G in each set of light emitting chip sets 140 in the same row are connected, and second electrodes 142 of the blue light emitting chip 140B in each set of light emitting chip sets 140 in the same row are connected, and so on. The second pads 122 corresponding to the same type of light emitting chip within all of the pad sets 120 in each row are connected, so that second electrodes 122 of the same type of light emitting chip of all light emitting chip sets 140 in each row may be connected, meanwhile, second pads 122 corresponding to the same type of light emitting chip in all of the pad sets 120 in the same row are electrically connected through the first connection line 123 and the third connection line 125 and then connected to the pin 130 through the fourth connection line 126, whereby the number of the pin 130 to be disposed may be reduced, while the arrangement of the lines of the fourth metal line layer may be avoided, and thus the risk of the pins 130 being shorted during the patching of the display module is reduced.

In addition, all first pads 121 within the same column of pad sets 120 are electrically connected, so that first electrodes 141 of light emitting chips within a column of light emitting chip sets 140 corresponding to the same column of pad sets 120 are connected, then are connected to the second connection line 124 through the fourth connection line 126, so that the first pad 121 is connected to the pin 130, thus a number of pins 130 may be disposed to be only 16 corresponding pads of the sixteen sets of pad sets 120, whereby the number of the pin 130 to be disposed may be reduced, the arrangement of the pins 130 may be simplified, and thus the arrangement of the pins 130 being symmetrically distributed about a function center is implemented, where the function center is a geometric center of the second surface 112.

Moreover, the fourth connection line 126 may be connected to the second connection line 123 and the third connection line 125, respectively, so that a position where the second connection line 123 and the third connection line 125 are connected to the pins 130 may be adjusted, thereby the arrangement of the pins 130 being symmetrically distributed about a function center is facilitated to implement, where the function center is a geometric center of the second surface 112.

With continued reference to FIGS. 2 to 5, in a row direction X in which the pad sets are arranged, the second pads 122 of an i-th column of pad sets 120 and the (i+1)-th column of pad sets 120 in the same row are adjacently disposed.

Specifically, when second pads 122 of the corresponding same type of light emitting chips in the i-th column of pad sets 120 and the (i+1)-th column of pad sets 120 in the same row are connected by the first connection line 123, the second pads 122 of the i-th column of pad sets 120 may be disposed adjacent to the second pads 122 of the (i+1)-th column of pad sets 120 in the row direction X, whereby the provision of the first connection lines 123 may be reduced while a phenomenon of overlapping short-circuiting with the first connection line 123 when the second connection lines 123 are used for connecting the same column of first pads 121 is avoided.

With continued reference to FIGS. 2 to 5, species of light emitting chip corresponding to the second pad 122 in the pad sets 120 of the same row are arranged to be the same in a column direction Y.

Specifically, the species of the light emitting chip corresponding to the second pads 122 are arranged to be the same in the same direction Y, so that when the first connection line 123 is connected to the second pad 122 of the corresponding same type of light emitting chip in the same row of pad sets 120, the first connection lines 123 may be arranged in a straight line, which advantageously reduces the length of the first connection line 123 while advantageously simplifies the arrangement of lines on the first metal line layer. Exemplarily, three types of light emitting chips within light emitting chip sets 140 corresponding to pad sets 120 located in the first row and the first column are arranged in the column direction Y according to a first row of green light emitting chips 140G, a second row of red light emitting chips 140R, and a third row of blue light emitting chips 140B, then three types of light emitting chips within light emitting chip sets 140 corresponding to pad sets 120 located in a first row and a second column, pad sets 120 located in a first row and a third column, and pad sets 120 located in a first row and a fourth column are likewise arranged in the column direction Y according to the first row of green light emitting chips 140G, the second row of red light emitting chips 140R, and the third row of blue light emitting chips 140B.

With continued reference to FIGS. 2 to 5, each set of light emitting chip sets 140 includes a red light emitting chip 140R, a green light emitting chip 140G, and a blue light emitting chip 140B; in the column direction Y in which the pad sets are arranged, the same set of light emitting chip sets 140 are arranged according to the first row of green light emitting chips 140G, the second row of red light emitting chips 140R, and the third row of blue light emitting chips 140B.

Specifically, within a set of light emitting chip sets 140, the three types of light emitting chips are arranged in the column direction in a straight line. Among the red light emitting chip 140R, the green light emitting chip 140G and the blue light emitting chip 140B, the red light emitting chip 140R has the most brittle material, the red light emitting chip 140R is disposed to be located between the green light emitting chip 140G and the blue light emitting chip 140B, the influence on the red light emitting chip 140R when a master mask of the display module is cut to form the display module during preparation may be reduced, the lifetime of the red light emitting chip 140R may be ensured, and further the reliability of the product may be improved.

Based on each of the above technical schemes, a size of the red light emitting chip 140R is larger than a size of the green light emitting chip 140G, and the size of the red light emitting chip 140R is larger than a size of the blue light emitting chip 140B, the size of the red light emitting chip 140R is less than twice the size of the green light emitting chip 140G, and/or the size of the red light emitting chip 140R is less than twice the size of the blue light emitting chip 140B.

Specifically, the red light emitting chip 140R is relatively fragile, and in the technical scheme of this embodiment, the size of the red light emitting chip 140R may be made relatively large to ensure the reliability of the red light emitting chip 140R after a cutting process. Exemplarily, the size of the red light emitting chip 140R may be 3*5 μm, and the sizes of the green light emitting chip 140 G and the blue light emitting chip 140B may be 2*4 μm.

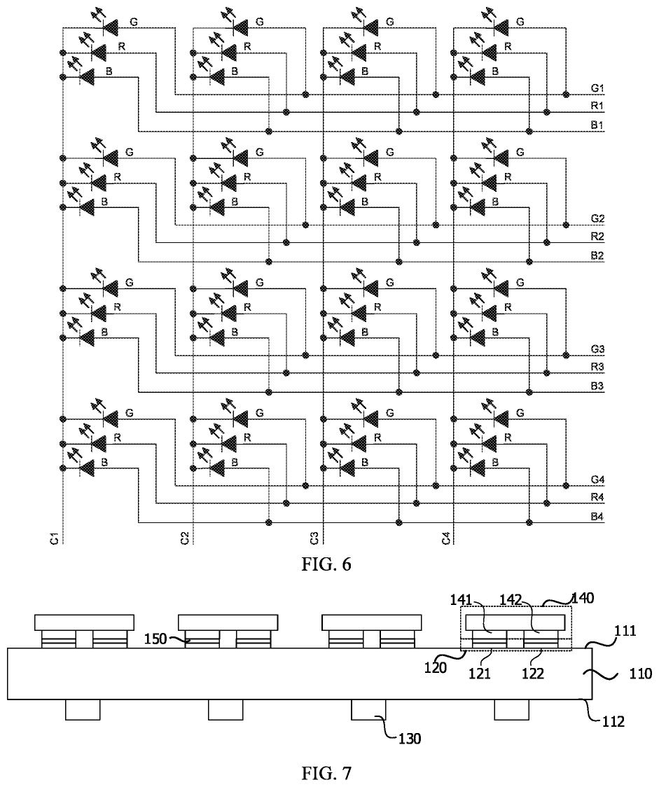

FIG. 6 is a connection principle diagram of a light emitting chip in a display module provided in an embodiment of the present disclosure, as shown in FIG. 6, in a first row of light emitting chip sets 140, second electrodes of all red light emitting chips R are electrically connected, second electrodes of all green light emitting chips G are electrically connected, and second electrodes of all blue light emitting chips B are electrically connected, and so on. Second electrodes of all same light emitting chips in each row of light emitting chip sets 140 share one pin 130, and first electrodes of all light emitting chips in each column of light emitting chip sets 140 share one pin 130.

FIG. 7 is a front structural schematic diagram of another display module provided in an embodiment of the present disclosure, and as shown in FIG. 7, the display module further includes a welding layer 150, the welding layer 150 is disposed on a side of a pad set 120 facing away from the first surface 111, an electrode of a light emitting chip set 140 is connected to the pad set 120 through the welding layer 150.

Specifically, the welding layer 150 may be a tin paste. Alternatively, the welding layer 150 may be a tin layer, and the welding layer 150 may be disposed on a pad, to form a tin-plated pad. Alternatively, the welding layer 150 may be disposed on the electrode of the light emitting chip set 140 to form a tinned electrode. When the electrode of the light emitting chip set 140 are connected to the pad set 120 through the welding layer 150, a flux may be provided before the die bonding, so that the size problem of the welding layer 150 may be avoided, and thus the yield of the die bonding may be effectively improved.

An embodiment of the present disclosure further provides a display panel. The display panel includes the display module provided in any of the embodiments of the present disclosure.

The display panel may include at least one display module according to a size. Since the display panel includes the display module provided in any of the embodiments of the present disclosure, and thus has beneficial effects of the display module provided in any of the embodiments of the present disclosure. When the display panel is formed, the test efficiency of the display panel may be improved and the test cost may be reduced.

What is claimed is:

1. A display module, comprising:
a substrate, comprising a first surface and a second surface disposed opposite to each other;
pad sets arranged in an array having m rows and n columns, wherein the pad sets are disposed on the first surface and each comprise three pairs of pads, each pair of pads among the three pairs of pads comprises a first pad and a second pad, and first pads in the each set of pad sets are electrically connected, wherein m≥2 and n≥2;
m*n sets of light emitting chip sets disposed on a side of the pad sets facing away from the first surface, wherein each set of the m*n sets of light emitting chip sets comprises three types of light emitting chips, and in a same set of light emitting chip sets, each of first electrodes of light emitting chips is connected to a respective one of first pads of one set of the pad sets, and each of second electrodes of light emitting chips is connected to a respective one of second pads of a same one set of pad sets; and
a plurality of pins comprising n first electrode pins and 3 m second electrode pins and disposed on the second surface, wherein one first electrode pin among the n first electrode pins is electrically connected to a common first pad corresponding to first electrodes of light emitting chips in one row of light emitting chip sets among the m*n sets of light emitting chip sets, and one second electrode pin among the 3 m second electrode pins is electrically connected to a second pad corresponding to a second electrode of a same type of light emitting chips in one column of light emitting chip sets among the m*n sets of light emitting chip sets; the n first electrode pins are symmetrically distributed about a geometric center of the second surface, and the 3 m second electrode pins are symmetrically distributed about the geometric center of the second surface.

2. The display module of claim 1, wherein the plurality of pins are divided into four types of function pins which are first function pins, second function pins, third function pins and fourth function pins, respectively, the first function pins correspond to the first electrode pins, the second function pins correspond to second electrode pins corresponding to of a first type of light emitting chips, the third function pins correspond to second electrode pins corresponding to a second type of light emitting chips, the fourth function pin corresponds to second electrode pins corresponding to a third type of light emitting chips, and the four types of function pins are symmetrically distributed about the geometric center of the second surface.

3. The display module of claim 2, wherein the second surface of the substrate is square, the first function pins are rotationally symmetric with respect to 90°, the second function pins are rotationally symmetric with respect to 90°, the third function pins are rotationally symmetric with respect to 90°, and the fourth function pins are rotationally symmetric with respect to 90°.

4. The display module of claim 1, wherein the substrate comprises N metal line layers sequentially stacked, and comprises an insulating plate between adjacent metal line layers, wherein the N metal line layers are electrically connected by conductive via holes on the insulating plate, and N≥2.

5. The display module of claim 4, wherein each of the first pad and the second pad is electrically connected to a respective one of the plurality of pins located on the second surface of the substrate through the conductive via holes, respectively, or each of the first pad and the second pad is electrically connected to a respective one of the plurality of pins located on the second surface of the substrate through the conductive via holes and the metal line layers of the substrate, respectively.

6. The display module of claim 5, wherein conductive via holes of each column of common first pads are disposed between same adjacent two rows of light emitting chip sets.

7. The display module of claim 1, comprising 16p sets of pad sets arranged in a square-shaped matrix, each set of pad sets among the 16p sets of pad sets comprises the three pairs of pads, first pads of each column of pad sets are electrically connected to the first electrode pins, respectively, and second pads of a same type of light emitting chips of each row of pad sets are electrically connected to the second electrode pins, respectively; and the plurality of pins are arranged in a square-shaped matrix, wherein p is an integer greater than or equal to 1.

8. The display module of claim 7, wherein the substrate comprises a first metal line layer, a second metal line layer, a third metal line layer and a fourth metal line layer which are stacked; the 16p sets of pad sets are arranged in a square-shaped matrix on the first metal line layer; and the plurality of pins are arranged in a square-shaped matrix on the fourth metal line layer; and
the first metal line layer is further provided with a first connection line and a second connection line, in a row direction of the pad sets, second pads which correspond to a same type of light emitting chip and are in an i-th column of pad sets and an (i+1)-th column of pad sets in a same row are connected by the first connection line, and first pads of the pad sets in a same column are connected through the second connecting line; wherein i is an odd number greater than or equal to 1 and less than 4p.

9. The display module of claim 8, wherein second pads of an i-th column of the pad sets and second pads of an (i+1)-th column of the pad sets in a same row are disposed adjacent to each other in the row direction of the pad sets.

10. The display module of claim 7, wherein the light emitting chips corresponding to the second pads in a same row of the pad sets have a same distribution of types in a column direction.

11. The display module of claim 1, further comprising a welding layer, wherein the welding layer is disposed on a side of the pad sets facing away from the first surface, electrodes of light emitting chip sets are connected to the pad sets via the welding layer, respectively.

12. The display module of claim 1, wherein a perpendicular projection of each of the plurality of pins on the substrate is polygonal or circular.

13. A display panel, comprising a display module comprising:
a substrate, comprising a first surface and a second surface disposed opposite to each other;
pad sets arranged in an array having m rows and n columns, wherein the pad sets are disposed on the first surface and each comprise three pairs of pads, each pair of pads among the three pairs of pads comprises a first pad and a second pad, and first pads in the each set of pad sets are electrically connected, wherein m≥2 and n≥2;
m*n sets of light emitting chip sets disposed on a side of the pad sets facing away from the first surface, wherein each set of the m*n sets of light emitting chip sets comprises three types of light emitting chips, and in a same set of light emitting chip sets, each of first electrodes of light emitting chips is connected to a respective one of first pads of one set of the pad sets, and each of second electrodes of light emitting chips is connected to a respective one of second pads of a same one set of pad sets; and
a plurality of pins comprising n first electrode pins and 3 m second electrode pins and disposed on the second surface, wherein one first electrode pin among the n first electrode pins is electrically connected to a common first pad corresponding to first electrodes of light emitting chips in one row of light emitting chip sets among the m*n sets of light emitting chip sets, and one second electrode pin among the 3 m second electrode pins is electrically connected to a second pad corresponding to a second electrode of a same type of light emitting chips in one column of light emitting chip sets among the m*n sets of light emitting chip sets; the n first electrode pins are symmetrically distributed about a geometric center of the second surface, and the 3 m second electrode pins are symmetrically distributed about the geometric center of the second surface.

14. The display panel of claim 13, wherein the plurality of pins are divided into four types of function pins which are first function pins, second function pins, third function pins and fourth function pins, respectively, the first function pins correspond to the first electrode pins, the second function pins correspond to second electrode pins corresponding to of a first type of light emitting chips, the third function pins correspond to second electrode pins corresponding to a second type of light emitting chips, the fourth function pin corresponds to second electrode pins corresponding to a third type of light emitting chips, and the four types of function pins are symmetrically distributed about the geometric center of the second surface.

15. The display panel of claim 14, wherein the second surface of the substrate is square, the first function pins are rotationally symmetric with respect to 90°, the second function pins are rotationally symmetric with respect to 90°, the third function pins are rotationally symmetric with respect to 90°, and the fourth function pins are rotationally symmetric with respect to 90°.

16. The display panel of claim 13, wherein the substrate comprises N metal line layers sequentially stacked, and comprises an insulating plate between adjacent metal line layers, wherein the N metal line layers are electrically connected by conductive via holes on the insulating plate, and N≥2.

17. The display panel of claim 16, wherein each of the first pad and the second pad is electrically connected to a respective one of the plurality of pins located on the second surface of the substrate through the conductive via holes, respectively, or each of the first pad and the second pad is electrically connected to a respective one of the plurality of pins located on the second surface of the substrate through the conductive via holes and the metal line layers of the substrate, respectively.

18. The display panel of claim 17, wherein conductive via holes of each column of common first pads are disposed between same adjacent two rows of light emitting chip sets.

19. The display panel of claim 13, comprising 16p sets of pad sets arranged in a square-shaped matrix, each set of pad sets among the 16p sets of pad sets comprises the three pairs of pads, first pads of each column of pad sets are electrically connected to the first electrode pins, respectively, and second pads of a same type of light emitting chips of each row of pad sets are electrically connected to the second electrode pins, respectively; and the plurality of pins are arranged in a square-shaped matrix, wherein p is an integer greater than or equal to 1.

20. The display panel of claim 18, wherein the substrate comprises a first metal line layer, a second metal line layer, a third metal line layer and a fourth metal line layer which are stacked; the 16p sets of pad sets are arranged in a square-shaped matrix on the first metal line layer; and the plurality of pins are arranged in a square-shaped matrix on the fourth metal line layer; and
the first metal line layer is further provided with a first connection line and a second connection line, in a row direction of the pad sets, second pads which correspond to a same type of light emitting chip and are in an i-th column of pad sets and an (i+1)-th column of pad sets in a same row are connected by the first connection line, and first pads of the pad sets in a same column are connected through the second connecting line; wherein i is an odd number greater than or equal to 1 and less than 4p.
